(19) United States
(12) Patent Application Publication
(10) Pub. No.: US 2026/0059913 A1
(43) Pub. Date: Feb. 26, 2026

(54) METHOD OF MANUFACTURING DISPLAY DEVICE AND ELECTRONIC DEVICE INCLUDING THE DISPLAY DEVICE

(71) Applicant: Samsung Display Co., Ltd., Yongin-si (KR)

(72) Inventors: Yun Young LEE, Yongin-si (KR); Eun Kyung YEON, Yongin-si (KR); Dong Sung LEE, Yongin-si (KR); Sung Kook LEE, Yongin-si (KR); Tae Hyeog JUNG, Yongin-si (KR); Byoung Jin JIN, Yongin-si (KR)

(21) Appl. No.: 19/288,435

(22) Filed: Aug. 1, 2025

(30) Foreign Application Priority Data
Aug. 22, 2024 (KR) 10-2024-0112771

(51) Int. Cl. H10H 29/01; H05K 1/18; H10H 29/80

(52) U.S. Cl. CPC H10H 29/034; H05K 1/189; H10H 29/842; H05K 2201/10128

(57) ABSTRACT

A method of manufacturing a display device includes forming a release frame exposing an uppermost surface of a display stack, wherein the display stack includes a first stack and a second stack sequentially stacked, and the uppermost surface of the display stack is an upper surface of the second stack, applying a first curable resin on the upper surface of the second stack and the release frame adjacent thereto, forming a flexible coating layer on the second stack by curing the first curable resin, and removing the release frame.

### CROSS-REFERENCE TO RELATED APPLICATION

The present application claims priority to and the benefit of Korean Patent Application No. 10-2024-0112771, filed on Aug. 22, 2024, in the Korean Intellectual Property Office, the entire disclosure of which is incorporated herein by reference.

### BACKGROUND

### 1. Field

Aspects of some embodiments of the present disclosure relate to a method of manufacturing a display device and an electronic device including the display device.

### 2. Description of the Related Art

A display device is a device that displays images. The display device may be implemented as a stack in which a plurality of layers having various functions are stacked. For example, the display device may include a second layer located on a first layer.

The above information disclosed in this Background section is only for enhancement of understanding of the background and therefore the information discussed in this Background section does not necessarily constitute prior art.

### SUMMARY

In a display device, the planar area of a second layer may be greater than a planar area of the first layer. In this case, when the second layer is directly formed on the first layer (for example, the second layer is formed on the first layer using an inkjet coating method), difficulty of a process for forming a portion of the second layer, which is not supported by the first layer, may become difficult.

Aspects of some embodiments of the present disclosure include an efficient method of manufacturing a display device with relatively low process difficulty.

According to some embodiments of the present disclosure, a method of manufacturing a display device includes forming a release frame exposing an uppermost surface of a display stack, wherein the display stack includes a first stack and a second stack sequentially stacked, and the uppermost surface of the display stack is an upper surface of the second stack, applying a first curable resin on the upper surface of the second stack and the release frame adjacent thereto, forming a flexible coating layer on the second stack by curing the first curable resin, and removing the release frame.

According to some embodiments, in a plan view, an area of the first stack may be greater than an area of the second stack.

According to some embodiments, in a plan view, an edge of the first stack may completely surround an edge of the second stack.

According to some embodiments, on a cross-section, the release frame may completely cover side surfaces of the second stack.

According to some embodiments, in applying the first curable resin, a first step area surrounding the second stack and a second step area surrounding the first step area may be defined, on a cross-section, in the first step area, an upper surface of the release frame may be aligned with the upper surface of the second stack, and on a cross-section, in the second step area, the upper surface of the release frame may be at a level higher than that of the upper surface of the second stack.

According to some embodiments, in forming the flexible coating layer, on a cross-section, in the second step area, the upper surface of the release frame may be aligned with an upper surface of the flexible coating layer.

According to some embodiments, in applying the first curable resin, the first curable resin may be applied on the upper surface of the second stack and the upper surface of the release frame overlapping the first step area.

According to some embodiments, in applying the first curable resin, the first curable resin may not be applied on the upper surface of the release frame overlapping the second step area.

According to some embodiments, in a plan view, an area of the flexible coating layer may be greater than an area of the second stack.

According to some embodiments, in a plan view, an edge of the flexible coating layer may completely surround an edge of the second stack.

According to some embodiments, the first curable resin may include a siloxane-based material and an epoxy-based material.

According to some embodiments, the first curable resin may be a UV curable resin.

According to some embodiments, forming the release frame may include fixing the display stack with a jig, which includes a lower jig including a receiving space for receiving the first stack and an upper jig on the lower jig and surrounding the second stack, applying a second curable resin between the upper jig and the second stack, pressurizing the second curable resin with a mold, and curing the second curable resin to form the release frame.

According to some embodiments, the mold may include a protruding surface protruding in a direction facing the second stack.

According to some embodiments, in a plan view, an area of the protruding surface may be greater than an area of the second stack.

According to some embodiments, the second curable resin may include a siloxane-based material.

According to some embodiments, the second curable resin may not be applied on the upper surface of the second stack.

According to some embodiments, the display stack may further include a flexible circuit board having one end on the first stack and spaced apart from the second stack, and a driver on the flexible circuit board.

According to some embodiments, in fixing the display stack with the jig, the driver may be interposed between the upper jig and the lower jig.

According to some embodiments, the method may further include disposing a protective layer on the flexible coating layer, after removing the release frame.

According to some embodiments of the present disclosure, an electronic device includes a processor to provide input image data, and a display device to display an image based on the input image data. The display device may be manufactured by using above described method.

In a method of manufacturing a display device according to some embodiments of the present disclosure, a release frame may serve to support a portion, which is not supported by a second stack having a relatively small planar area, in a first curable resin applied to have a relatively large planar area. By curing the first curable resin, a flexible coating layer may be formed on the second stack.

Accordingly, difficulty of a process of directly forming the flexible coating layer having a relatively large planar area on the second stack having a relatively small planar area may be lowered.

### BRIEF DESCRIPTION OF THE DRAWINGS

The above and other aspects of embodiments according to the present disclosure will become more apparent by describing in further detail aspects of embodiments thereof with reference to the accompanying drawings, in which:

FIG. 1 is a perspective view illustrating a display device according to some embodiments of the disclosure;

FIG. 2 is a cross-sectional view taken along the line I1-I1′ of FIG. 1;

FIG. 3 is a cross-sectional view illustrating a panel layer of FIG. 2;

FIGS. 4 to 25 are drawings illustrating a method of manufacturing a display device according to some embodiments of the present disclosure; and

FIGS. 26 to 35 are drawings illustrating a method of manufacturing a display device according to some embodiments of the present disclosure.

FIG. 36 is a schematic block diagram illustrating an electronic device including a display device according to some embodiments of the present disclosure.

FIG. 37 is a schematic diagram illustrating an example where the electronic device of FIG. 36 is a smartphone.

FIG. 38 is a schematic diagram illustrating an example where the electronic device of FIG. 36 is a tablet computer.

### DETAILED DESCRIPTION

Hereinafter, aspects of some embodiments of the present disclosure are described in more detail with reference to the accompanying drawings. It should be noted that in the following description, only portions necessary for understanding an operation according to the disclosure are described, and descriptions of other portions are omitted in order not to obscure the subject matter of the disclosure. In addition, the disclosure may be embodied in other forms without being limited to the embodiments described herein. However, the embodiments described herein are provided to describe in sufficient detail to implement the technical spirit of the disclosure by those skilled in the art to which the disclosure belongs.

Throughout the specification, in a case where a portion is “connected” to another portion, the case includes not only a case where the portion is “directly connected” but also a case where the portion is “indirectly connected” with another element interposed therebetween. Terms used herein are for describing specific embodiments and are not intended to limit the disclosure. Throughout the specification, in a case where a certain portion “includes”, the case means that the portion may further include another component without excluding another component unless otherwise stated. “At least any one of X, Y, and Z” and “at least any one selected from an array consisting of X, Y, and Z” may be interpreted as one X, one Y, one Z, or any combination of two or more of X, Y, and Z (for example, XYZ, XYY, YZ, and ZZ). Here, “and/or” includes all combinations of one or more of corresponding configurations.

Here, terms such as first and second may be used to describe various components, but these components are not limited to these terms. These terms are used to distinguish one component from another component. Therefore, a first component may refer to a second component within a range without departing from the scope disclosed herein.

Spatially relative terms such as “under”, “on”, and the like may be used for descriptive purposes, thereby describing a relationship between one element or feature and another element(s) or feature(s) as shown in the drawings. Spatially relative terms are intended to include other directions in use, in operation, and/or in manufacturing, in addition to the direction depicted in the drawings. For example, when a device shown in the drawing is turned upside down, elements depicted as being positioned “under” other elements or features are positioned in a direction “on” the other elements or features. Therefore, in the present disclosure, the term “under” may include both directions of on and under. In addition, the device may face in other directions (for example, rotated 90 degrees or in other directions) and thus the spatially relative terms used herein are interpreted according thereto.

Aspects of some embodiments are described in further detail with reference to drawings schematically illustrating ideal embodiments. Accordingly, it will be expected that shapes may vary, for example, according to tolerances and/or manufacturing techniques. Therefore, the embodiments disclosed herein cannot be construed as being limited to shown specific shapes, and should be interpreted as including, for example, changes in shapes that occur as a result of manufacturing. As described above, the shapes shown in the drawings may not show actual shapes of areas of a device, and the present embodiments are not limited thereto.

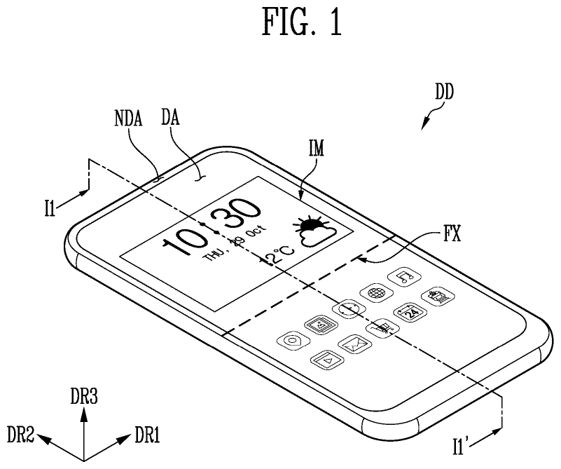

FIG. 1 is a perspective view illustrating a display device according to some embodiments of the present disclosure.

Referring to FIG. 1, the display device DD may include a display area DA and a non-display area NDA.

The display area DA may be an area where an image IM is displayed. For example, the display area DA may be implemented on a plane defined by a first direction DR1 and a second direction DR2. A third direction DR3 may be a direction perpendicular or normal to the first and second directions DR1 and DR2. In the present specification, the phrases “on a plane” or “in a plan view” may refer to an orientation, which is viewed from the third direction DR3 toward the display area DA.

The non-display area NDA may be arranged around (e.g., in a periphery or outside a footprint of) the display area DA. In the non-display area NDA, various types of circuits and lines generating and/or transmitting various signals necessary for displaying the image IM in the display area DA may be located.

According to some embodiments, the display device DD may be a foldable display device. For example, the display device DD may be folded and unfolded like a book, based on a folding axis FX parallel to the first direction DR1, without damaging the display device DD.

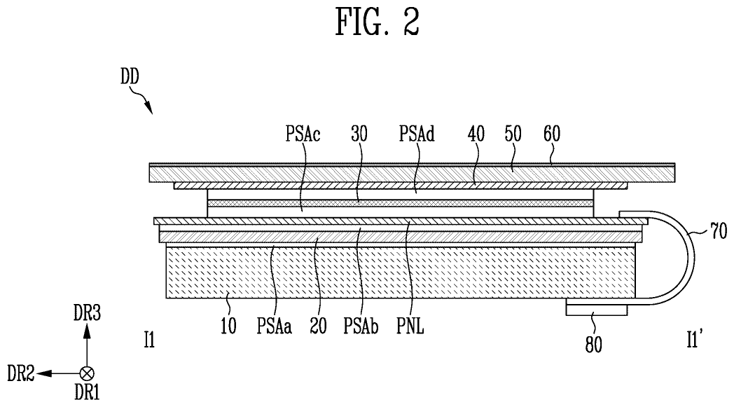

FIG. 2 is a cross-sectional view taken along the line I1-I1′ of FIG. 1.

Referring to FIG. 2, the display device DD may include a plate 10, a lower protective layer 20, a panel layer PNL, an impact absorbing layer 30, a flexible coating layer 40, a first protective layer 50, a second protective layer 60, first to fourth adhesive layers PSAa, PSAb, PSAc, and PSAd, a flexible circuit board 70, and a driver 80.

The plate 10 may have relatively high rigidity. The plate 10 may serve to support components located on the plate 10.

The lower protective layer 20 may be located on the plate 10. The lower protective layer 20 may serve to block an impurity diffusing from the plate 10.

The first adhesive layer PSAa may be interposed between the lower protective layer 20 and the plate 10. The lower protective layer 20 and the plate 10 may be adhered to each other by the first adhesive layer PSAa.

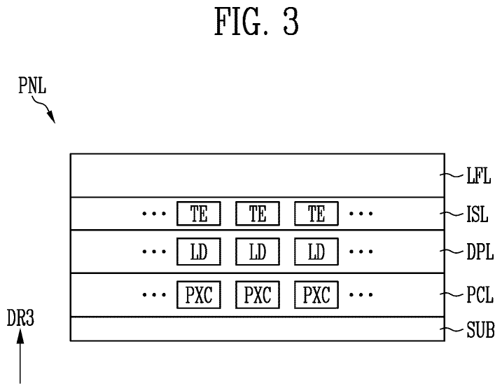

The panel layer PNL may be located on the lower protective layer 20. The panel layer PNL may include various components for providing the image IM. The panel layer PNL is described in detail later with reference to FIG. 3.

The second adhesive layer PSAb may be interposed between the panel layer PNL and the lower protective layer 20. The panel layer PNL and the lower protective layer 20 may be adhered to each other by the second adhesive layer PSAb.

The impact absorbing layer 30 may be located on the panel layer PNL. The impact absorbing layer 30 may protect components located under the impact absorbing layer 30 from external force. For example, the impact absorbing layer 30 may include a material having excellent damping performance.

The third adhesive layer PSAc may be interposed between the impact absorbing layer 30 and the panel layer PNL. The impact absorbing layer 30 and the panel layer PNL may be adhered to each other by the third adhesive layer PSAc.

The flexible coating layer 40 may be located on the impact absorbing layer 30. The flexible coating layer 40 may have rigidity greater than that of the impact absorbing layer 30, and may have a relatively flexible property (flexibility).

The fourth adhesive layer PSAd may be interposed between the flexible coating layer 40 and the impact absorbing layer 30. The flexible coating layer 40 and the impact absorbing layer 30 may be adhered to each other by the fourth adhesive layer PSAd.

The first protective layer 50 may be located on the flexible coating layer 40. The first protective layer 50 may have rigidity greater than that of the flexible coating layer 40. The first protective layer 50 may serve to protect components located under the first protective layer 50 from external force. According to some embodiments, the first protective layer 50 may be referred to as a cover window. In this case, the first protective layer 50 may include glass or plastic.

The second protective layer 60 may be located on the first protective layer 50. The second protective layer 60 may serve to prevent or reduce instances of a trace (for example, a fingerprint trace) remaining due to contact with the user of the display device DD.

One end of the flexible circuit board 70 may be located on the panel layer PNL. The driver 80 may be located on the flexible circuit board 70. The driver 80 may provide an electrical signal to a pixel circuit PXC of FIG. 3 of a pixel circuit layer PCL of FIG. 3 through lines included in the flexible circuit board 70 and lines included in the panel layer PNL.

According to some embodiments, a portion of the flexible circuit board 70 may be bent. Accordingly, the driver 80 located on the flexible circuit board 70 may be located under the plate 10.

According to some embodiments, various types of layers configuring the display device DD may have different areas (or sizes). For example, on a cross-section of FIG. 2, a width of the second direction DR2 of the flexible coating layer 40 may be greater than a width of the second direction DR2 of the fourth adhesive layer PSAd located directly under the flexible coating layer 40.

FIG. 3 is a cross-sectional view illustrating the panel layer of FIG. 2.

Referring to FIG. 3, the panel layer PNL may include a substrate SUB, and the pixel circuit layer PCL, a display element layer DPL, an input sensing layer ISL, and a light function layer LFL sequentially stacked along the third direction DR3 on the substrate SUB.

The substrate SUB may be formed of an insulating material such as glass or resin. For example, the substrate SUB may include a glass substrate. As another example, the substrate SUB may include a polyimide (PI) substrate. As still another example, the substrate SUB may include a silicon wafer substrate formed using a semiconductor process.

In embodiments, the substrate SUB may be formed of a flexible material that may be bent or folded, and may have a single-layer structure or a multi-layer structure. For example, the flexible material may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, or cellulose acetate propionate. However, embodiments according to the present disclosure are not limited thereto.

The pixel circuit layer PCL may be located on the substrate SUB. The pixel circuit layer PCL may include insulating layers and semiconductor patterns and conductive patterns located between the insulating layers. The semiconductor patterns and the conductive patterns of the pixel circuit layer PCL may function as circuit elements (for example, a transistor and/or a capacitor), lines, and the like.

These circuit elements and lines may define a pixel circuit PXC. A plurality of pixel circuits PXC may be provided.

The display element layer DPL may be located on the pixel circuit layer PCL. The display element layer DPL may include a light emitting element LD. The light emitting element LD may be connected to the pixel circuit PXC of the pixel circuit layer PCL. The light emitting element LD may emit light based on an electric signal provided by the pixel circuit PXC. A plurality of light emitting element LD may be provided.

The input sensing layer ISL may be located on the display element layer DPL. The input sensing layer ISL may include a sensing electrode TE. The sensing electrode TE may sense an input of a user of the display device DD (for example, an external object such as a hand of the user or a pen). A plurality of sensing electrode TE may be provided.

The light functional layer LFL may be located on the input sensing layer ISL. The light functional layer LFL may include light conversion patterns including color conversion particles and/or scattering particles. For example, the color conversion particles may include quantum dots. The quantum dots may change a wavelength (or color) of light emitted from the display element layer DPL. The light functional layer LFL may further include light scattering patterns having the scattering particles. In embodiments, the light conversion patterns and the light scattering patterns may be omitted.

The light functional layer LFL may further include a color filter layer including color filters. The color filter may selectively transmit light of a specific wavelength (or a specific color). In embodiments, the color filter layer may be omitted.

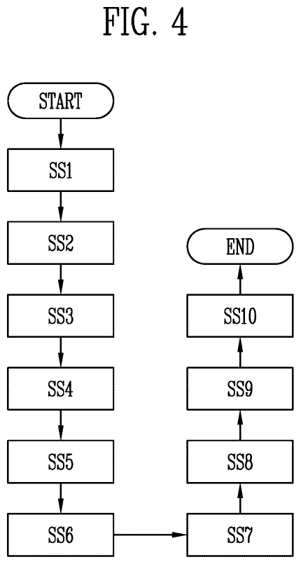

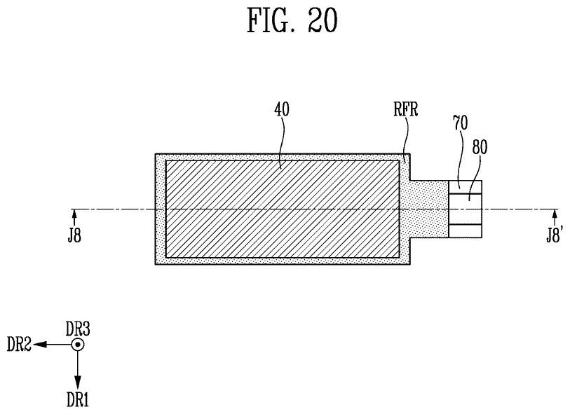

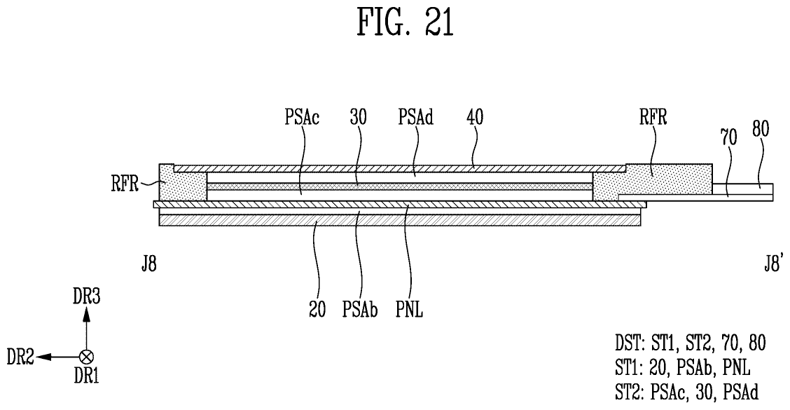

FIGS. 4 to 25 are drawings illustrating a method of manufacturing a display device according to some embodiments of the present disclosure. Although FIGS. 4-25 illustrate various operations in a method of manufacturing a display device, embodiments according to the present disclosure are not limited thereto, and according to various embodiments, the method may include additional operations, or fewer operations, or the order of operations may vary, unless otherwise stated or implied, without departing from the spirit and scope of embodiments according to the present disclosure.

Referring to FIG. 4, the method of manufacturing the display device DD may include operations 1 to 10 SS1 to SS10.

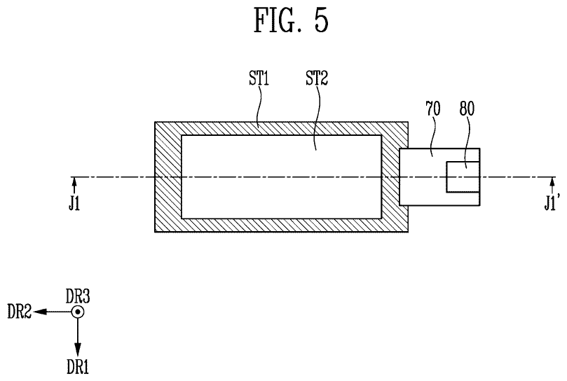

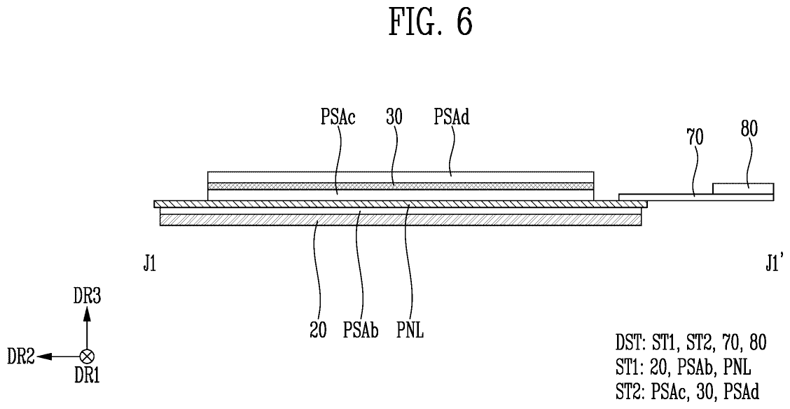

Referring to FIGS. 5 and 6, a display stack DST including a first stack ST1 and a second stack ST2 sequentially stacked in the third direction DR3 may be provided (SS1).

The first stack ST1 may include a lower protective layer 20, a second adhesive layer PSAb, and a panel layer PNL sequentially stacked along the third direction DR3. The second stack ST2 may include a third adhesive layer PSAc, an impact absorbing layer 30, and a fourth adhesive layer PSAd sequentially stacked along the third direction DR3.

According to some embodiments, the planar areas of the lower protective layer 20 and the second adhesive layer PSAb may be equal (or substantially equal) to each other. The lower protective layer 20 and the second adhesive layer PSAb may completely (or substantially completely) overlap on a plane (or in a plan view).

According to some embodiments, the planar area of the panel layer PNL may be greater than the planar area of the lower protective layer 20 and greater than the planar area of the second adhesive layer PSAb.

According to some embodiments, the planar areas of the third adhesive layer PSAc, the impact absorbing layer 30, and the fourth adhesive layer PSAd may be equal (or substantially equal) to each other. The third adhesive layer PSAc, the impact absorbing layer 30, and the fourth adhesive layer PSAd may completely (or substantially completely) overlap on a plane (or in a plan view).

According to some embodiments, the planar area of the first stack ST1 may be greater than the planar area of the second stack ST2. In this case, on a plane (or in a plan view), an edge of the first stack ST1 may completely surround an edge of the second stack ST2. For example, on a plane (or in a plan view), an edge of the panel layer PNL configuring the first stack ST1 may completely surround an edge of the fourth adhesive layer PSAd configuring the second stack ST2.

According to some embodiments, the display stack DST may further include a flexible circuit board 70 and a driver 80.

One end of the flexible circuit board 70 may be located on the first stack ST1. For example, one end of the flexible circuit board 70 may be located on the panel layer PNL. The flexible circuit board 70 may be spaced apart from the second stack ST2.

The driver 80 may be located on the flexible circuit board 70. The driver 80 may provide an electrical signal to the pixel circuit PXC of the pixel circuit layer PCL through lines included in the flexible circuit board 70 and lines included in the panel layer PNL.

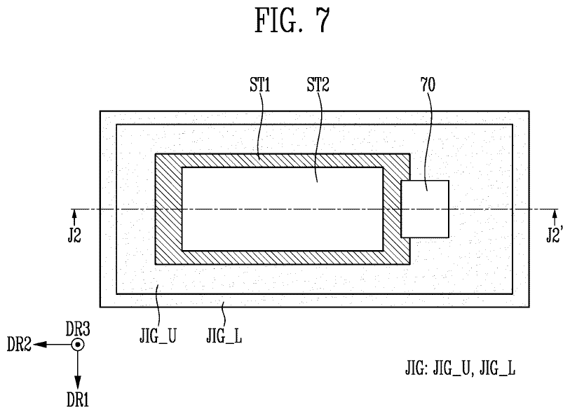

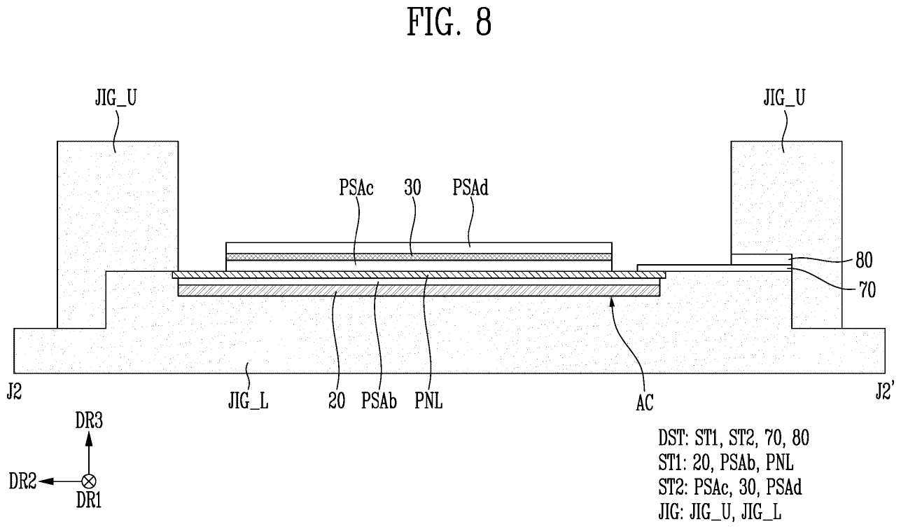

Referring to FIGS. 7 and 8, the display stack DST may be fixed by a jig JIG (SS2).

According to some embodiments, the jig JIG may include a lower jig JIG_L and an upper jig JIG_U.

The lower jig JIG_L may include a receiving space AC for receiving the first stack ST1. The receiving space AC may be depressed in a direction opposite to the third direction DR3 and may have a shape corresponding to a shape of the first stack ST1. According to some embodiments, a level of an upper surface of the lower jig JIG_L adjacent to the receiving space AC may be the same (or substantially the same) as a level of an upper surface of the panel layer PNL, which is the uppermost surface of the first stack ST1.

The upper jig JIG_U may be fastened on the lower jig JIG_L. In this case, a portion of the driver 80 and the flexible circuit board 70 may be interposed between the upper jig JIG_U and the lower jig JIG_L.

The upper jig JIG_U may be provided to surround the second stack ST2. In this case, on a plane (or in a plan view), an inner edge of the upper jig JIG_U may be spaced apart from the edge of the second stack ST2 and may completely surround the edge of the second stack ST2. The upper jig JIG_U may be spaced apart from the second stack ST2. In addition, a level of an upper surface of the upper jig JIG_U may be higher than a level of an upper surface of the second stack ST2.

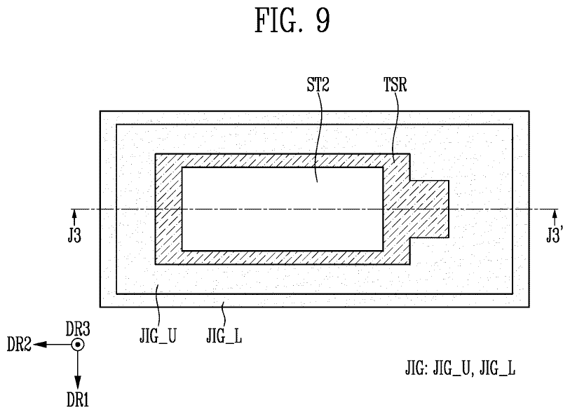

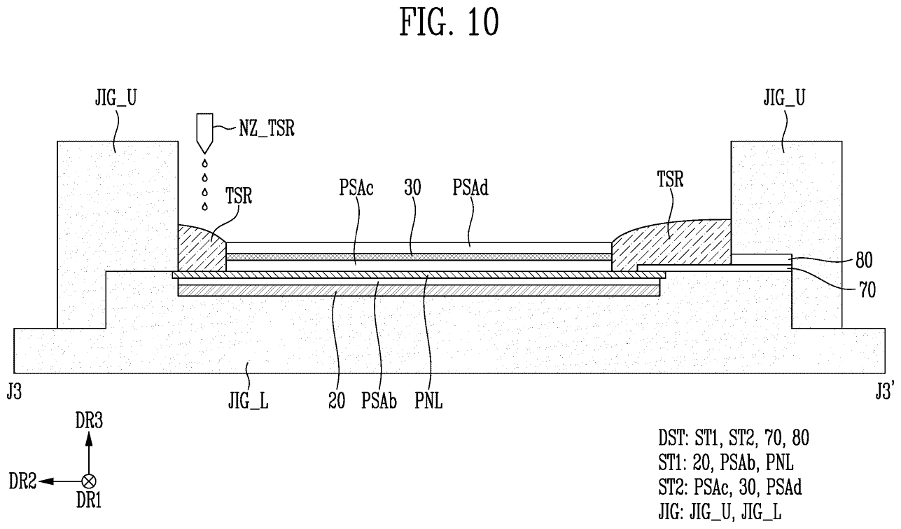

Referring to FIGS. 9 and 10, a second curable resin TSR may be applied between the upper jig JIG_U and the second stack ST2 (SS3).

According to some embodiments, the second curable resin TSR may include a siloxane-based material. For example, the second curable resin TSR may be polydimethylsiloxane (PDMS). The second curable resin TSR may be a thermosetting resin.

According to some embodiments, the second curable resin TSR may not be applied on the upper surface of the second stack ST2. The second curable resin TSR may be applied by an inkjet method using a nozzle NZ_TSR, and in this case, the second curable resin TSR may be selectively applied to a separation space between the second stack ST2 and the upper jig JIG_U.

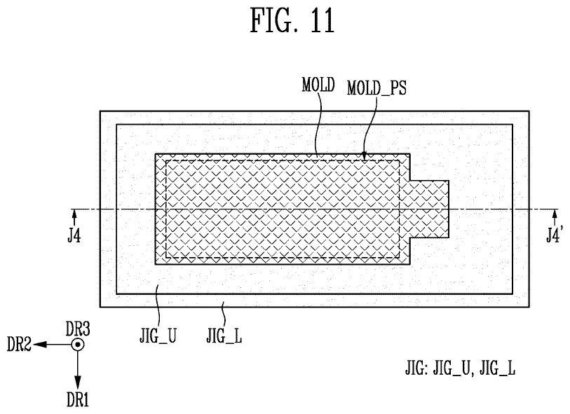

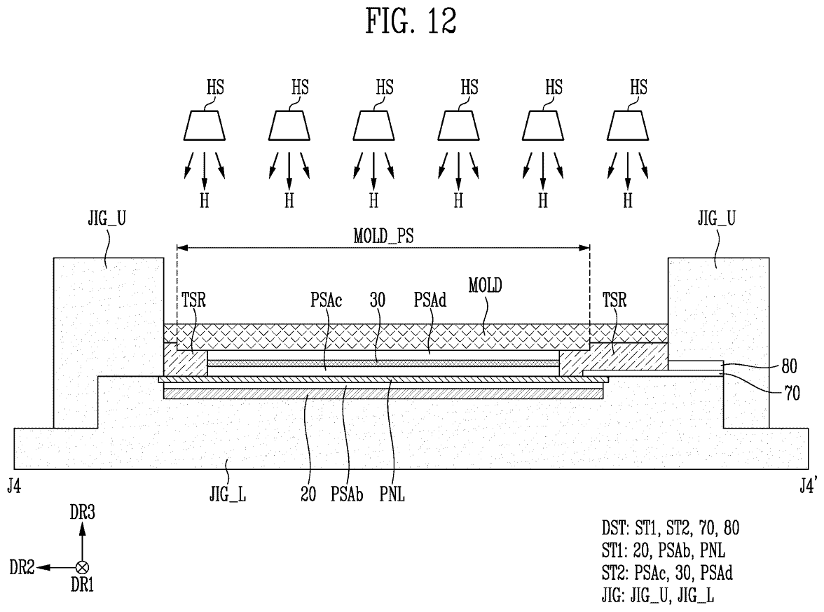

Referring to FIGS. 11 and 12, the second curable resin TSR may be pressed by a mold MOLD (SS4).

According to some embodiments, the mold MOLD may include a protruding surface MOLD_PS that protrudes in a direction facing the second stack ST2. On a plane (or in a plan view), the area of the protruding surface MOLD_PS may be greater than the area of the second stack ST2. In addition, on a plane (or in a plan view), an edge of the protruding surface MOLD_PS may completely surround the edge of the second stack ST2.

The protruding surface MOLD_PS of the mold MOLD may be directly contact the entire upper surface of the second stack ST2. Side surfaces of the mold MOLD may directly contact inner surfaces of the upper jig JIG_U.

By pressure by the mold MOLD, the second curable resin TSR may be deformed into a shape corresponding to a shape of the mold MOLD.

Referring to FIGS. 12 to 14, in a state in which the second curable resin TSR is pressed by the mold MOLD, heat H may be provided from a heat source HS. Accordingly, the second curable resin TSR may be hardened to form a release frame RFR (SS5). After this operation, the mold MOLD may be removed.

The release frame RFR may have a shape corresponding to the shape of the second curable resin TSR pressed by the mold MOLD described with reference to FIG. 12. For example, according to some embodiments, on a plane (or in a plan view), a first step area STA1 surrounding the second stack ST2 and a second step area STA2 surrounding the first step area STA1 may be defined. In the first step area STA1, on a cross-section, an upper surface of the release frame RFR may be aligned with the upper surface of the second stack ST2. In the second step area STA2, on a cross-section, the upper surface of the release frame RFR may be located at a level higher than the upper surface of the second stack ST2. That is, the release frame RFR may have a step between the first step area STA1 and the second step area STA2. On a cross-section, the release frame RFR may completely cover side surfaces of the second stack ST2 and may expose the upper surface of the second stack ST2.

According to some embodiments, because the second curable resin TSR provided to form the release frame RFR includes a siloxane-based material, the release frame RFR may have sufficient release force. That is, the release frame RFR may be easily separated from the display stack DST.

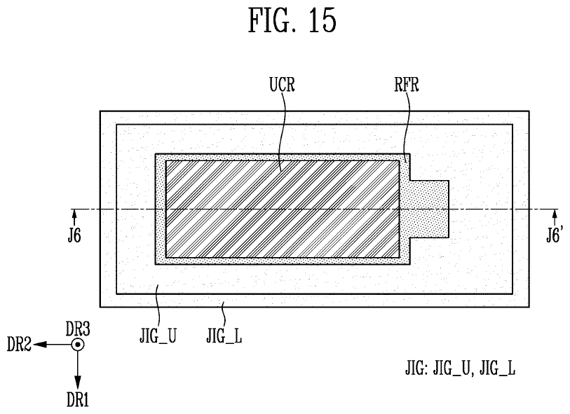

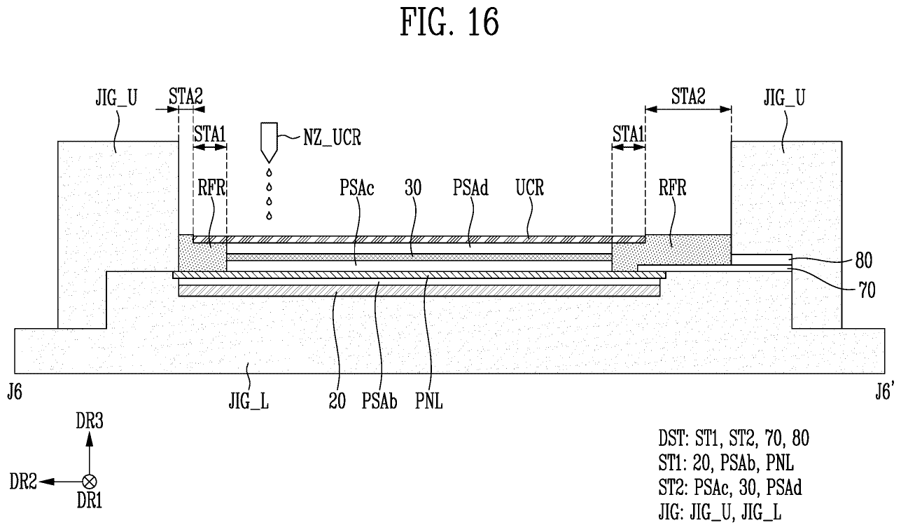

Referring to FIGS. 15 and 16, a first curable resin UCR may be applied on the upper surface of the second stack ST2 and the release frame RFR adjacent thereto (SS6).

According to some embodiments, the first curable resin UCR may include a siloxane-based material and an epoxy-based material. The siloxane-based material may impart excellent rigidity to the first curable resin UCR. The epoxy-based material may impart excellent flexibility to the first curable resin UCR. The first curable resin UCR may be a photocurable resin.

According to some embodiments, the first curable resin UCR may be applied on the upper surface of the second stack ST2 and the upper surface of the release frame RFR overlapping the first step area STA1. The first curable resin UCR may not be applied on the upper surface of the release frame RFR overlapping the second step area STA2. The first curable resin UCR may be applied by an inkjet method using a nozzle NZ_UCR, and in this case, the first curable resin UCR may be selectively applied in an area surrounded by the second step area STA2.

According to some embodiments, the planar area of the first curable resin UCR may be greater than the planar area of the second stack ST2. On a plane (or in a plan view), an edge of the first curable resin UCR may completely surround the edge of the second stack ST2. In this case, a portion of the first curable resin UCR, which is not supported by the second stack ST2, may be supported by the release frame RFR.

As described above, in this operation, the release frame RFR may serve to support the portion of the first curable resin UCR, which is not be supported by only the second stack ST2 having the relatively small planar area.

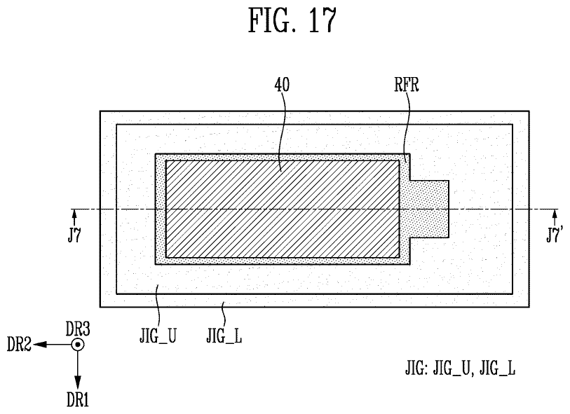

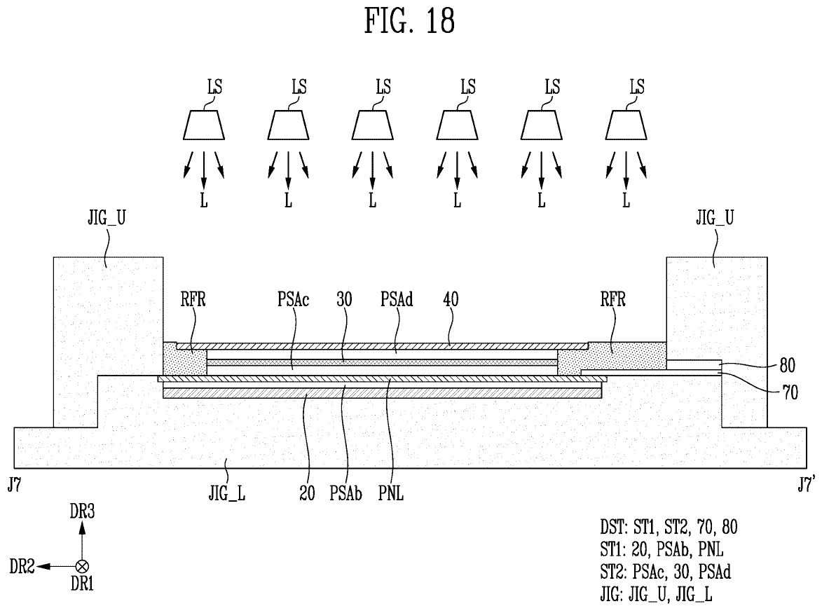

Referring to FIGS. 17 and 18, light L may be provided from a light source LS. The light L may be, for example, UV light. Accordingly, the first curable resin UCR may be cured to form a flexible coating layer 40 on the second stack ST2 (SS7).

According to some embodiments, on a plane (or in a plan view), the area of the flexible coating layer 40 may be greater than the area of the second stack ST2. On a plane (or in a plan view), an edge of the flexible coating layer 40 may completely surround the edge of the second stack ST2.

As described above, in operation SS6, because the portion of the first curable resin UCR, which is not supported only by the second stack ST2 having the relatively small planar area is supported by the release frame RFR, difficult of a process for directly forming the flexible coating layer 40 having the relatively large planar area on the second stack ST2 having the relatively small planar area may be lowered.

According to some embodiments, because the first curable resin UCR provided to form the flexible coating layer 40 includes a siloxane-based material and an epoxy-based material, the flexible coating layer 40 may have sufficient rigidity and sufficient flexibility.

According to some embodiments, in the second step area STA2, on a cross-section, the upper surface of the release frame RFR may be aligned with an upper surface of the flexible coating layer 40.

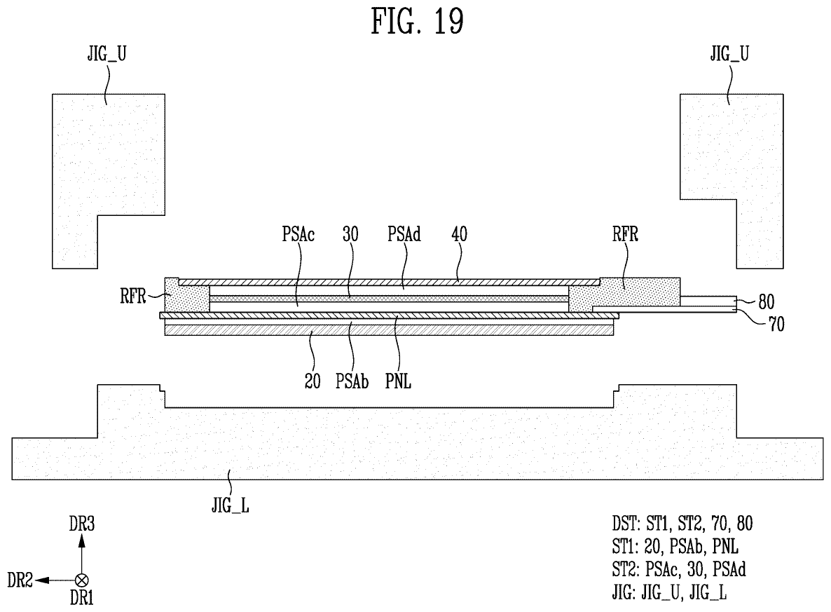

Referring to FIGS. 19 to 21, the jig JIG may be separated from the display stack DST and the release frame RFR (SS8).

Separation of the jig JIG may be performed, for example, by separating the upper jig JIG_U from the lower jig JIG_L and separating the display stack DST from the lower jig JIG_L, by moving the upper jig JIG_U which is fastened to the lower jig JIG_L in the third direction DR3.

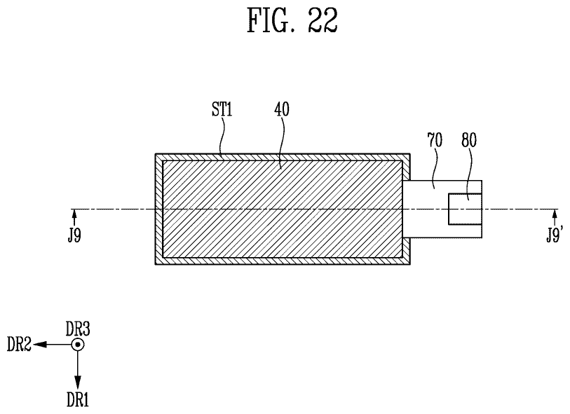

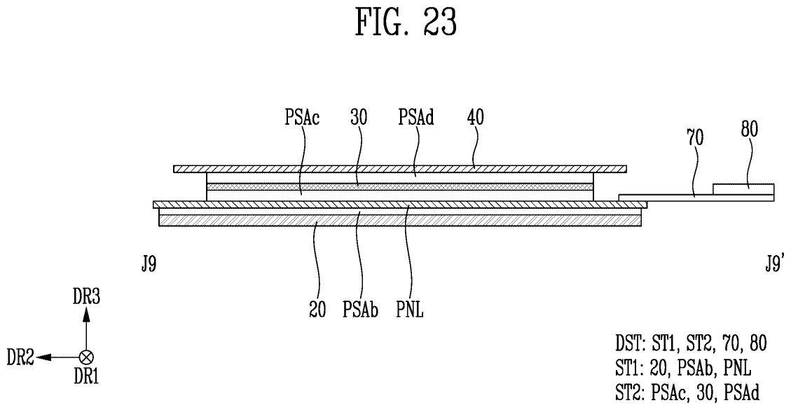

Referring to FIGS. 22 and 23, the release frame RFR may be removed (SS9).

As described above, because the release frame RFR has sufficient release force as the release frame RFR includes a siloxane-based material, the release frame RFR may be easily separated from the display stack DST. For example, the release frame RFR may be removed from the display stack DST by a physical method.

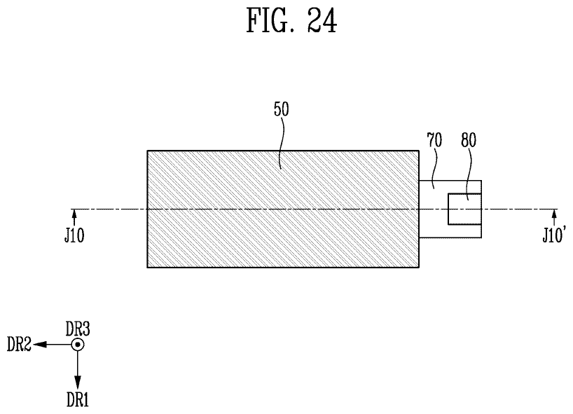

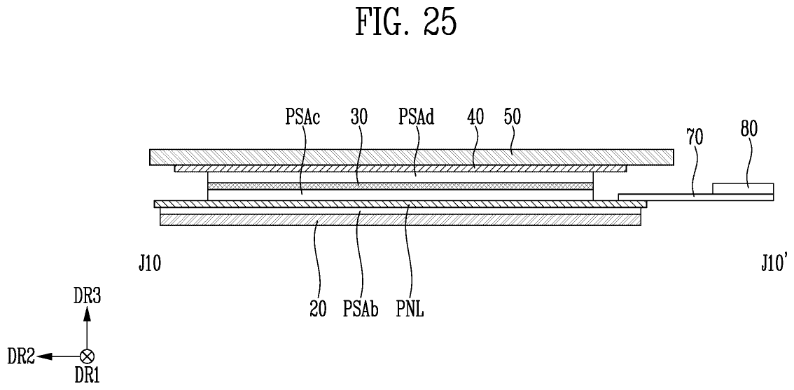

Referring to FIGS. 24 and 25, a first protective layer 50 may be located on the flexible coating layer 40 (SS10).

After this operation, operations in which various components configuring the display device DD described with reference to FIG. 2 are further located may be performed. Accordingly, the display device DD may be provided.

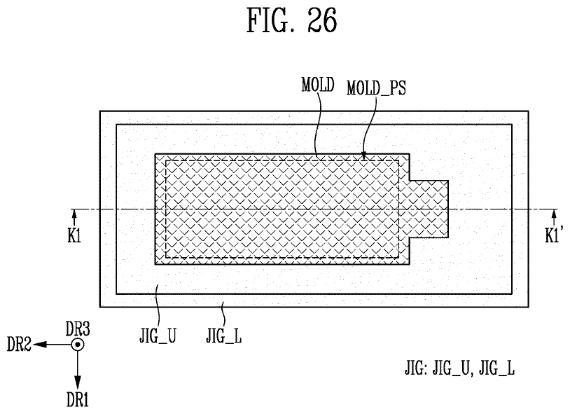

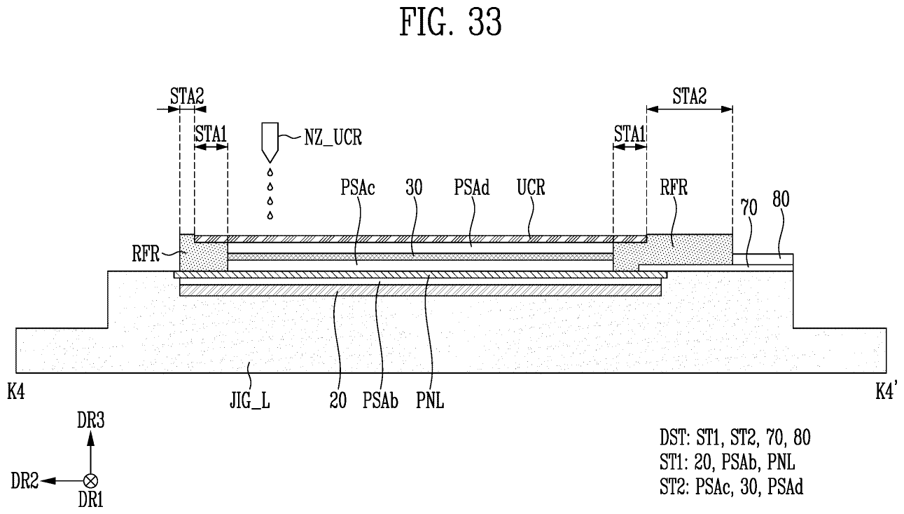

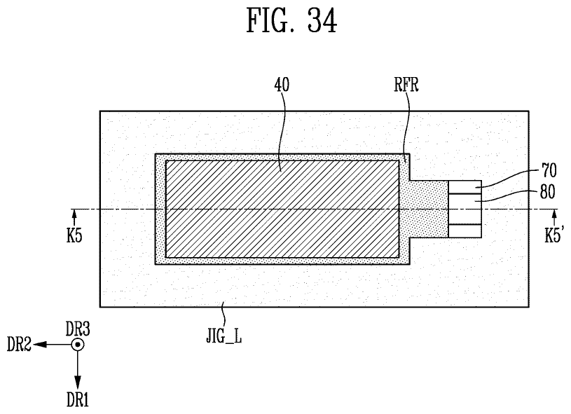

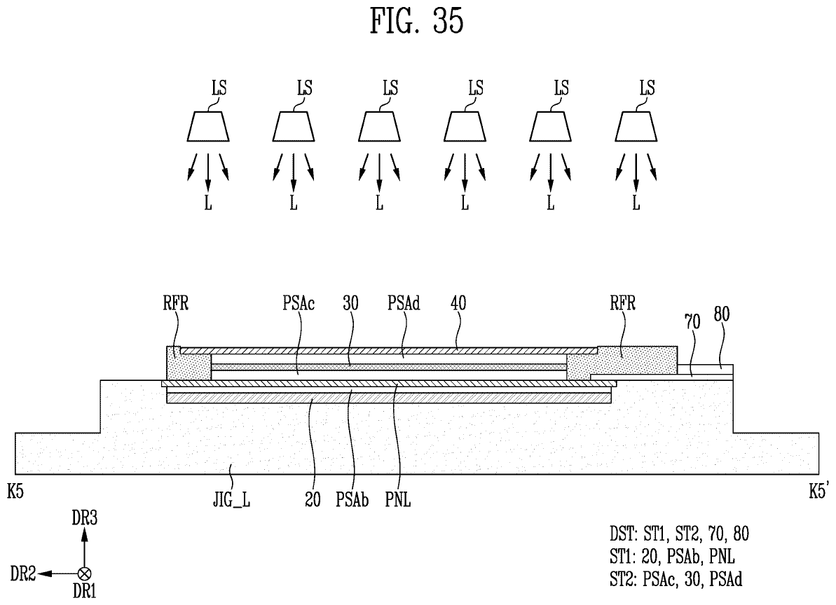

FIGS. 26 to 35 are diagrams illustrating a method of manufacturing a display device according to some embodiments of the present disclosure. In describing the method of manufacturing the display device of FIGS. 26 to 35, a difference compared to the embodiments described with reference to FIGS. 4 to 25 is mainly described, and a portion of which a description is omitted is replaced with the content described above.

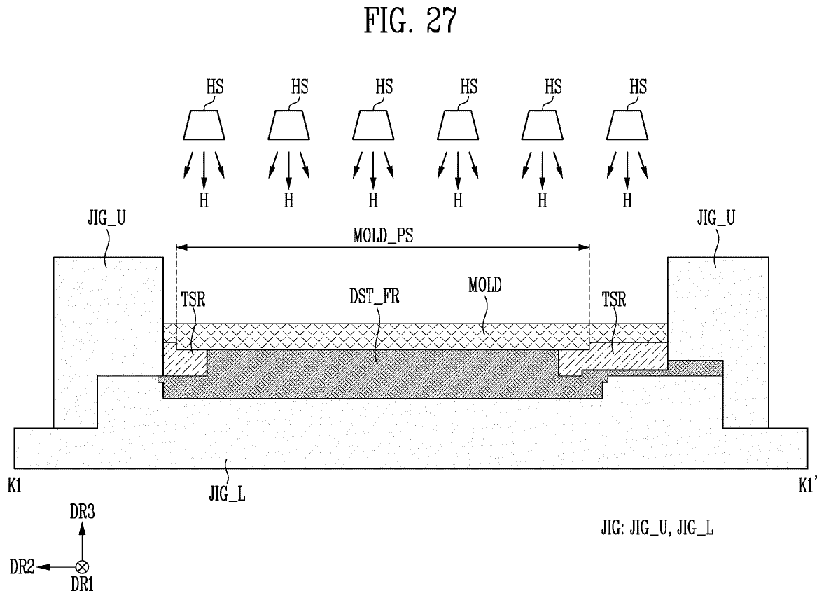

Referring to FIGS. 26 and 27, operation SS4 described with reference to FIGS. 11 and 12 may be performed identically (or substantially identically), except that a display stack corresponding frame DST_FR is used instead of the display stack DST. The display stack corresponding frame DST_FR may have the same (or substantially the same) shape as the display stack DST shown in FIGS. 11 and 12.

According to some embodiments, the display stack corresponding frame DST_FR may be formed integrally with the lower jig JIG_L.

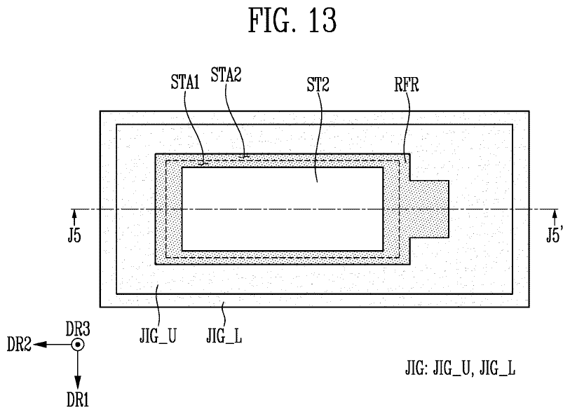

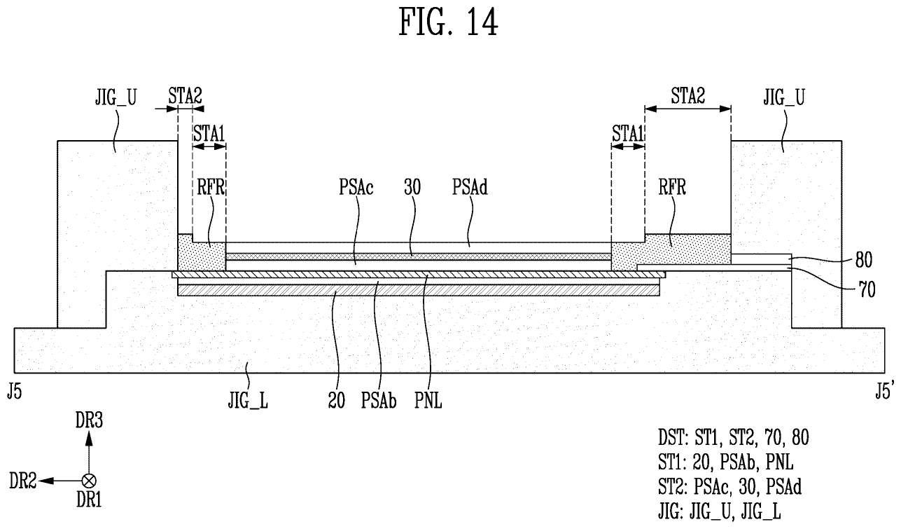

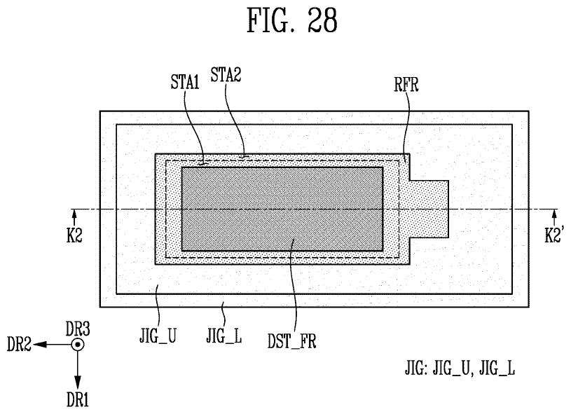

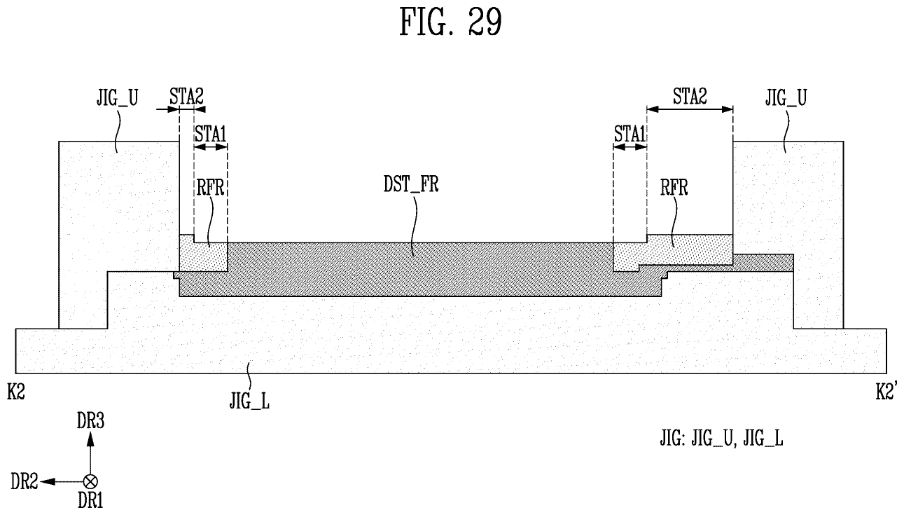

Referring to FIGS. 27 to 29, the release frame RFR may be formed in the same (or substantially the same) method as operation SS5 described with reference to FIGS. 12 to 14. Here, because the display stack corresponding frame DST_FR has the same (or substantially the same) shape as the display stack DST, the release frame RFR of FIGS. 28 and 29 may also have the same shape as the release frame RFR of FIGS. 13 and 14.

After this operation, the release frame RFR may be separated from other components.

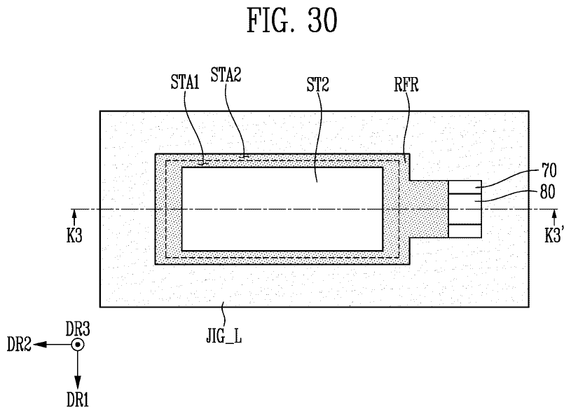

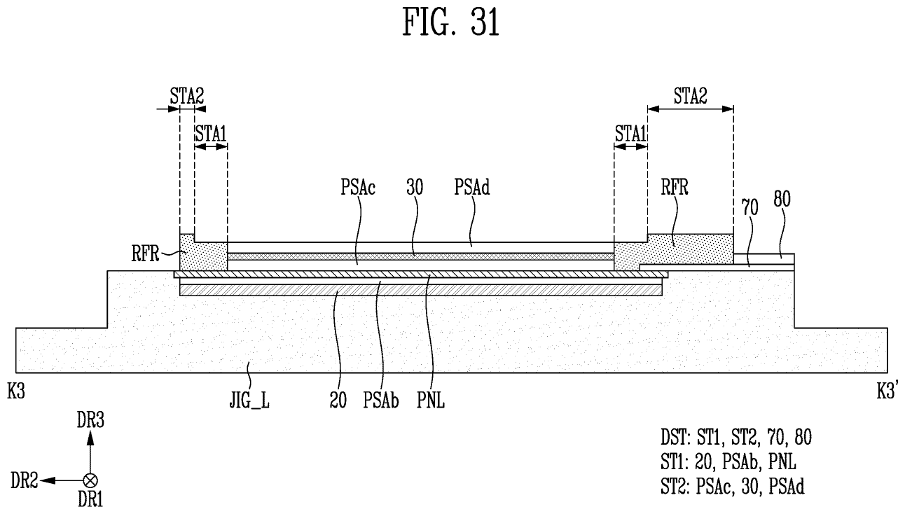

Referring to FIGS. 30 and 31, after the display stack DST is fixed on the lower jig JIG_L, the separated release frame RFR may be provided (or formed) on the display stack DST fixed to the lower jig JIG_L. In this case, the upper jig JIG_U may be omitted compared to operation described with reference to FIGS. 13 and 14.

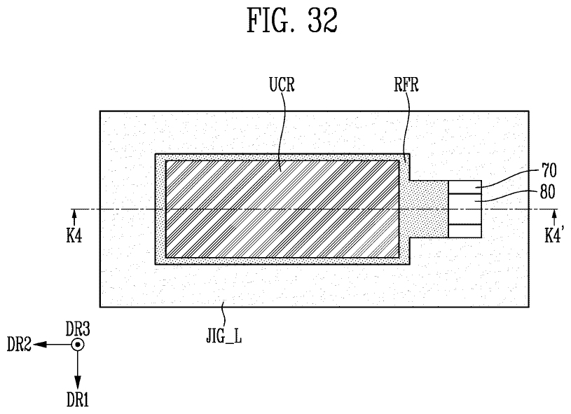

Referring to FIGS. 32 to 35, operations SS6 and SS7 described with reference to FIGS. 15 to 18 may be performed identically (or substantially identically) (or similarly). Accordingly, the flexible coating layer 40 may be formed on the second stack ST2.

After this operation, operations SS8, SS9, and SS10 described with reference to FIGS. 19 to 25 may be performed identically (or substantially identically) (or similarly).

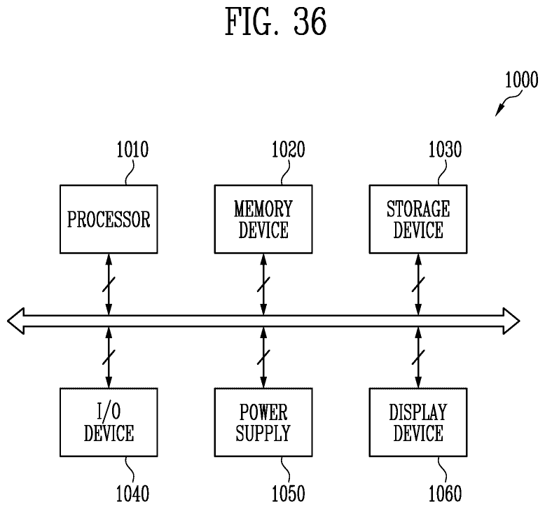

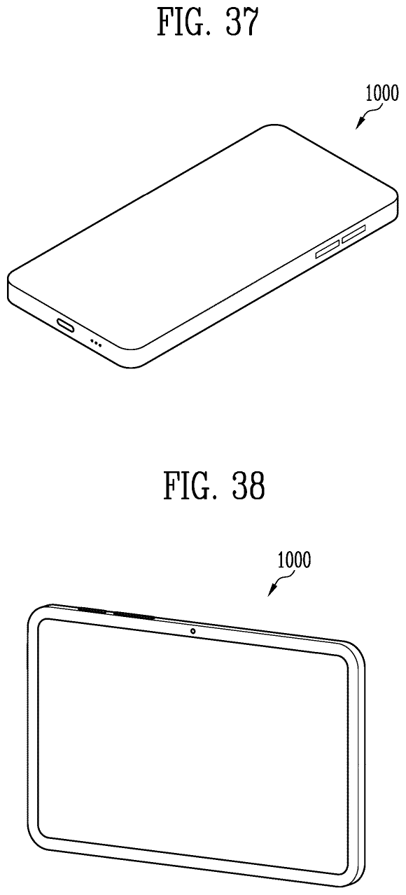

FIG. 36 is a schematic block diagram illustrating an electronic device including a display device according to some embodiments of the present disclosure. FIG. 37 is a schematic diagram illustrating an example where the electronic device of FIG. 36 is a smartphone. FIG. 38 is a schematic diagram illustrating an example where the electronic device of FIG. 36 is a tablet computer.

Referring to FIGS. 36 to 38, an electronic device 1000 may include a processor 1010, a memory device 1020, a storage device 1030, an input/output (I/O) device 1040, a power supply 1050, and a display device 1060. The display device 1060 may be the display device DD of FIGS. 1 to 3. The electronic device 1000 may further include various ports for communication with a video card, a sound card, a memory card, a USB device, or other systems. According to some embodiments, as illustrated in FIG. 37, the electronic device 1000 may be a smartphone. According to some embodiments, as illustrated in FIG. 38, the electronic device 1000 may be a tablet computer. However, the aforementioned examples are illustrative, and the electronic device 1000 is not necessarily limited to the aforementioned examples. For example, the electronic device 1000 may be a cellular phone, a video phone, a smart pad, a smartwatch, a navigation device for vehicles, a computer monitor, a laptop computer, a head-mounted display device, or the like.

The processor 1010 may perform specific calculations or tasks. According to some embodiments, the processor 1010 may be a microprocessor, a central processing unit, an application processor, or the like. The processor 1010 may be connected to other components through an address bus, a control bus, a data bus, and the like. According to some embodiments, the processor 1010 may be connected to an expansion bus such as a peripheral component interconnect (PCI) bus. According to some embodiments, the processor 1010 may provide input image data to the display device 1060. Hence, the display device 1060 may display an image based on the input image data provided from the processor 1010.

The memory device 1020 may store data needed to perform the operation of the electronic device 1000. The memory device 1020 may function as a working memory and/or a buffer memory for the processor 1010. For example, the memory device 1020 may include one or more volatile memory devices such as a dynamic random access memory (DRAM) device, a static random access memory (SRAM) device, and a mobile DRAM device.

The storage device 1030 may store data in response to control signals or data from the processor 1010. The storage device 1030 may include one or more non-volatile storages to retain the data even when the electronic device 1000 is powered off. In some embodiments, the storage device 1030 may include a solid state drive (SSD), a hard disk drive (HDD), a CD-ROM, or the like.

The I/O device 1040 may include input devices such as a keyboard, a keypad, a touchpad, a touch screen, and a mouse, and output devices such as a speaker and a printer. According to some embodiments, the display device 1060 may be integrated with the I/O device 1040.

The power supply 1050 may supply power needed to perform the operation of the electronic device 1000. For example, the power supply 1050 may include a power management integrated circuit (PMIC). According to some embodiments, the power supply 1050 may supply power to the display device 1060.

The display device 1060 may display images in response to control signals or data from the processor 1010. The display device 1060 may be connected to other components through the buses or other communication links.

Although described with reference to the above embodiments, it will be understood that those skilled in the art can variously modify and change the disclosed embodiments of the present disclosure without departing from the spirit and scope of embodiments according to the present disclosure as described in the claims below, and their equivalents.

What is claimed is:

1. A method of manufacturing a display device, the method comprising:
forming a release frame exposing an uppermost surface of a display stack, wherein the display stack includes a first stack and a second stack sequentially stacked, and the uppermost surface of the display stack is an upper surface of the second stack;
applying a first curable resin on the upper surface of the second stack and the release frame adjacent thereto;
forming a flexible coating layer on the second stack by curing the first curable resin; and
removing the release frame.

2. The method according to claim 1, wherein in a plan view, an area of the first stack is greater than an area of the second stack.

3. The method according to claim 2, wherein, in the plan view, an edge of the first stack completely surrounds an edge of the second stack.

4. The method according to claim 1, wherein, on a cross-section, the release frame completely covers side surfaces of the second stack.

5. The method according to claim 1, wherein in applying the first curable resin,
a first step area surrounding the second stack and a second step area surrounding the first step area are defined,
on a cross-section, in the first step area, an upper surface of the release frame is aligned with the upper surface of the second stack, and
on a cross-section, in the second step area, the upper surface of the release frame is at a level higher than that of the upper surface of the second stack.

6. The method according to claim 5, wherein in forming the flexible coating layer,
on a cross-section, in the second step area, the upper surface of the release frame is aligned with an upper surface of the flexible coating layer.

7. The method according to claim 5, wherein in applying the first curable resin,
the first curable resin is applied on the upper surface of the second stack and the upper surface of the release frame overlapping the first step area.

8. The method according to claim 7, wherein in applying the first curable resin,
the first curable resin is not applied on the upper surface of the release frame overlapping the second step area.

9. The method according to claim 1, wherein in a plan view, an area of the flexible coating layer is greater than an area of the second stack.

10. The method according to claim 9, wherein in the plan view, an edge of the flexible coating layer completely surrounds an edge of the second stack.

11. The method according to claim 1, wherein the first curable resin includes a siloxane-based material and an epoxy-based material.

12. The method according to claim 11, wherein the first curable resin is a UV curable resin.

13. The method according to claim 1, wherein forming the release frame comprises:
fixing the display stack with a jig, wherein the jig includes a lower jig including a receiving space for receiving the first stack and an upper jig on the lower jig and surrounding the second stack;
applying a second curable resin between the upper jig and the second stack;
pressurizing the second curable resin with a mold; and
curing the second curable resin to form the release frame.

14. The method according to claim 13, wherein the mold includes a protruding surface protruding in a direction facing the second stack.

15. The method according to claim 14, wherein, in a plan view, an area of the protruding surface is greater than an area of the second stack.

16. The method according to claim 13, wherein the second curable resin includes a siloxane-based material.

17. The method according to claim 13, wherein the second curable resin is not applied on the upper surface of the second stack.

18. The method according to claim 13, wherein the display stack further comprises:
a flexible circuit board having one end on the first stack and spaced apart from the second stack; and
a driver on the flexible circuit board, wherein
in fixing the display stack with the jig, the driver is interposed between the upper jig and the lower jig.

19. The method according to claim 1, further comprising forming a protective layer on the flexible coating layer, after removing the release frame.

20. An electronic device, comprising:
a processor to provide input image data; and
a display device to display an image based on the input image data, wherein
the display device is manufactured by using the method according to any one of claim 1.
